(19) United States
(12) Patent Application Publication
(10) Pub. No.: US 2009/0072329 A1
(43) Pub. Date: Mar. 19, 2009

(54) SEMICONDUCTOR DEVICE AND METHOD OF MANUFACTURING THE SAME

(75) Inventors: Takakazu KIYOMURA, Tokyo (JP); Takuo OHASHI, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: ELPIDA MEMORY, INC., Tokyo (JP)

(21) Appl. No.: 12/212,341

(22) Filed: Sep. 17, 2008

(30) Foreign Application Priority Data
Sep. 18, 2007 (JP) 2007-240859

(51) Int. Cl. H01L 29/78; H01L 21/336

(52) U.S. Cl. 257/411; 438/301; 257/E29.255; 257/E21.409

(57) ABSTRACT

The semiconductor device includes a field effect transistor comprising a gate insulating film having the film thickness of 1 nm or more, wherein at least an area of the gate insulating film which extending up to 1 nm from the side of the semiconductor layer in the thickness direction thereof comprises a silicon oxynitride film (SiON), the atom number ratio (O/Si) of oxygen to silicon in the area is 0.01 to 0.30, and the atom number ratio (N/Si) of nitrogen to silicon in the area is 0.05 to 0.30.

This application is based upon and claims the benefit of priority from Japanese Patent Application No. 2007-240859, filed on Sep. 18, 2007, the disclosure of which is incorporated herein in its entirety by reference.

### BACKGROUND OF THE INVENTION

1. Field of the Invention

The present invention relates to a semiconductor device comprising a field effect transistor including a thin gate insulating film with a special composition, and a method of manufacturing the semiconductor device.

2. Description of the Related Art

### [Constituent Material of the Gate Insulating Film]

With the yearly increased capacities and scales of semiconductor devices, the semiconductor devices have been miniaturized. The miniaturization of the semiconductor devices has reduced a minimum feature size in a pattern size based on a planar lithography technique as well as the film thickness of an insulating film and the like, which is a vertical dimension. For example, as a gate insulating film for a transistor, an extremely thin gate insulating film having a film thickness of 3 nm or less has been demanded.

However, when a related silicon oxide film is used as a gate insulating film, various problems occur at a film thickness of 3 nm or less.

For example, the reduced thickness of the gate insulating film directly increases a gate leakage current caused by a tunnel phenomenon.

Thus, to solve this problem, efforts have been made to develop methods using a gate insulating film composed of a material with a higher relative dielectric constant than the silicon oxide film. The gate insulating film using the high-relative-dielectric-constant material allows an insulating film capacity equivalent to that of an SiO₂ gate insulating film with a physically large film thickness to be achieved even with a small film thickness. As a result, a possible tunnel current can be directly inhibited.

Proposed examples of the high-relative-dielectric-constant material include SiON (Si₃N₄), HfSiON, HfAlON, HfZrSiON, HfZrAlON, and ZrAlON. These films are produced by a MOCVD (Metal-Organic Chemical Vapor Deposition) method, an ALD method, a sputtering method, or the like.

### [Interface Composition of the Gate Insulating Film]

In related field effect transistors (FETs), a silicon oxide film (SiO₂), a silicon oxynitride film (SiON), or the like is commonly used as a gate insulating film. An interface composition will be described in which the silicon oxide film (SiO₂) or the silicon oxynitride film (SiON) is used as a related gate insulating film.

FIG. 1 is a graph showing, for a silicon oxide film formed by thermal oxidation, the depth (nm) from the surface of a gate insulating film on the axis of abscissa and the composition rates of elements on the axis of ordinate. FIG. 2 illustrates, for the silicon oxide film same as in FIG. 1, the depth from the surface of the gate insulating film on the axis of abscissa and the O/Si atom number ratio on the axis of ordinate. In FIGS. 1 and 2, a position of 0 nm on the axis of abscissa indicates the gate electrode-side surface of the gate insulating film. The figures illustrate that an area extending 2 to 3 nm as illustrated on the axis of abscissa indicates the area in which a silicon dioxide composition changes gradually to a silicon-only composition. The figures also illustrate that the interface between the gate insulating film and a silicon substrate lies at a depth of 3 nm on the axis of abscissa and that an area with a depth of 3 nm or more corresponds to the silicon substrate.

However, as illustrated in FIG. 2, the O/Si ratio of the silicon oxide film changes rapidly from 0 to 2.0 in the vicinity of an Si substrate interface, which corresponds to 2 to 3 nm on the axis of abscissa. In this gate insulating film, since the Si substrate interface is sufficiently oxidized, interface level density can be minimized. However, since the Si concentration of the interface is low, the relative dielectric constant of the gate insulating film is prevented from being increased.

Thus, possible means for improving the relative dielectric constant of the gate insulating film is to produce an SiON film by subjecting the gate insulating film material to thermal nitriding.

FIG. 3 is a graph illustrating, for a silicon oxynitride film containing a large amount of nitrogen, the depth (nm) from the surface of the gate insulting film on the axis of abscissa and the composition rates of elements on the axis of ordinate. FIG. 4 illustrates, for the silicon oxynitride film containing the large amount of nitrogen same as in FIG. 3, the depth (nm) from the surface of the gate insulting film on the axis of abscissa and the atom number ratios of O/Si and N/Si on the axis of ordinate.

As shown in FIG. 3, when a large amount of nitrogen is present in the gate insulating film, most of the nitrogen is present in an area with a depth of about 1 to 2 nm on the axis of abscissa (depth). FIG. 3 indicates that nitrogen with a high concentration is present down to the vicinity of the Si substrate interface. FIG. 4 illustrates that in this case, the O/Si ratio is 0 to 0.7 and the N/Si ratio is 0 to 0.9 in the vicinity of the Si substrate interface, corresponding to 2 to 3 nm on the axis of abscissa. This means that the gate insulating film is nitrided down to the vicinity of the Si substrate interface.

Thus, the thermal nitriding of the gate insulating film material enables an increase in relative dielectric constant compared to the formation of a silicon oxide film by thermal oxidation. However, since the 10 gate insulating film in the vicinity of the interface is also nitrided, there is a fear that the interface level density may increase. The increased interface level may subject carriers in FET to interface scattering, reducing carrier mobility and transistor speed. Consequently, nitriding of the vicinity of the interface needs to be minimized.

Thus, to solve these problems, methods have been proposed which change the nitrogen concentration profile of the interface of the gate insulating film.

According to a method disclosed in Japanese Patent Laid-Open No. 2005-150637, first, the surface of a silicon substrate is subjected to plasma nitriding to form a silicon nitride film on the surface. Subsequently, the silicon nitride film is irradiated with oxygen plasma and thus oxidized to form a silicon oxide film and a silicon oxynitride film. This method has been reported to reduce the nitrogen atom concentration in the vicinity of the interface between the gate insulating film and the silicon substrate to at 5% or less.

According to a method disclosed in Japanese Patent Laid-Open No. 2003-078132, first, a gate insulating film made up of a silicon oxynitride (SiON) film with a high relative dielectric constant is formed on a silicon substrate. Then, the substrate is subjected to plasma oxidization via the silicon oxynitride (SiON) film to promote diffusion of oxygen to the silicon substrate interface to form a silicon oxide film. Subsequently, the resulting structure is subjected to post annealing to reduce fixed charges in the film.

Methods disclosed in Japanese Patent Laid-Open Nos. 2005-158998 and 2005-079223, respectively, use a gate insulating film made up of hafnium silicate (HfSiO) or the like. A silicon oxynitride film, a silicon nitride film, or a silicon oxide film is formed on the surface of the gate insulating film as an anti-reaction film. Then, fixed charges between the surface of the gate insulating film and a gate electrode are inhibited by the anti-reaction film.

According to a method disclosed in Japanese Patent Laid-Open No. 2004-281494, first, a high-relative-dielectric-constant film is deposited as a gate insulating film. Then, the film is subjected to interface oxidization and nitriding to reduce the interface level density and to inhibit possible fixed charges.

According to a method disclosed in D. Matsushita “Novel Fabrication Process to Realize Ultra-thin (EOT=0.7 nm) and Ultra-low Leakage SiON Gate Dielectrics” Symposium VLSI Tech, p. 172 to 173, 2004, first, a silicon nitride film (Si₃N₄) is formed on a silicon substrate. Then, the substrate is thermally oxidized via the silicon nitride film to oxidize the silicon substrate interface. The oxidization reduces the interface level density.

That is, the methods disclosed in the above references change the nitrogen concentration profile of the interface of the gate insulating film by the following methods.

(1) A first method is to reduce the amount of nitrogen in the gate insulating film. By way of example, FIGS. 5 and 6 illustrate the composition distribution in the depth direction and the O/Si ratio and N/Si ratio, respectively, for a gate insulating film with the nitrogen amount reduced. FIGS. 5 and 6 indicate that the reduced nitrogen amount reduces the N/Si ratio in the vicinity of the interface to about 0 to 0.3, enabling a reduction in interface level density compared to the case of a large nitrogen amount.

(2) A second method is to form a high-relative-dielectric-constant material and a silicon oxide film on the interface of the silicon substrate, which is at a low interface level, so that the laminate film of the silicon oxide film and the high-dielectric-constant film serves as a gate insulating film. This method provides a gate insulating film generally offering a high relative dielectric constant, while reducing the interface level density of the silicon substrate interface.

(1) However, as illustrated in FIG. 6, with the first method using the gate insulating film made up of the SiON film with the reduced nitrogen amount, the N/Si ratio in the vicinity of the Si substrate interface can be reduced, but the O/Si ratio in the vicinity of the Si substrate interface at a film thickness of 2 to 3 nm is 0 to 1.8, indicating a rapid increase in oxygen amount. Thus, this gate insulating film fails to offer a high relative dielectric constant compared to a gate insulating film made up of an SiON film with a large nitrogen amount.

(2) Furthermore, the reduction in film thickness which can be achieved by the second method is limited. Thus, this method disadvantageously fails to cope effectively with the need for a very thin gate insulating film. That is, the silicon oxide film needs to have the minimum required film thickness in order to reduce the interface level density, and the achievable film thickness of the silicon oxide film is limited. Thus, to obtain a thin gate insulating film, the SiON film formed on the silicon oxide film needs to be thinned. However, thinning the SiON film makes the adverse effect of the silicon oxide film having a low relative dielectric constant more significant. This prevents a capacity value from being effectively increased. That is, even with the SiON film, which offers a high relative dielectric constant, the silicon oxide film present on the interface side of the silicon substrate reduces the relative dielectric constant of the whole gate insulating film.

Thus, the related SiON film obtained by nitriding the silicon oxide film fails to achieve both an increase in relative dielectric constant and a reduction in interface level density.

We have now discovered that both an increase in relative dielectric constant and a reduction in interface level density can be achieved by forming a silicon oxynitride film (SiON) having a particular O/Si ratio and a particular N/Si ratio as a gate insulating film in the vicinity of the semiconductor layer.

### SUMMARY

The present invention seeks to solve one or more of the above problems, or to improve upon those problems at least in part.

In one embodiment, there is provided a semiconductor device including a field effect transistor comprising:

a semiconductor layer;

a gate electrode formed over the semiconductor layer;

a gate insulating film having a film thickness of 1 nm or more formed between the semiconductor layer and the gate electrode; and

a source area and a drain area formed in the semiconductor layer on both sides sandwiching the gate electrode,

wherein at least an area of the gate insulating film extending up to 1 nm from a side of the semiconductor layer in a thickness direction thereof comprises a silicon oxynitride film (SiON),

an atom number ratio (O/Si) of oxygen to silicon in the area is 0.01 to 0.30, and

an atom number ratio (N/Si) of nitrogen to silicon in the area is 0.05 to 0.30.

In another embodiment, there is provided a semiconductor device including a planar-type field effect transistor comprising a gate insulating film formed on a semiconductor layer,

wherein at least an area of the gate insulating film extending up to 1 nm from a side of the semiconductor layer in a thickness direction thereof comprises a silicon oxynitride film (SiON),

an atom number ratio (O/Si) of oxygen to silicon in the area is 0.01 to 0.30, and

an atom number ratio (N/Si) of nitrogen to silicon in the area is 0.05 to 0.30.

In another embodiment, there is provided a semiconductor device including a planar-type field effect transistor comprising:

a gate insulating film formed on a semiconductor layer; and

a gate electrode formed on the gate insulating film,

wherein at least an area of the gate insulating film extending up to 1 nm from a side of the semiconductor layer in a thickness direction thereof comprises an HfSiON film,

an atom number ratio (O/Si) of oxygen to silicon in the area is 0.01 to 0.30, and

an atom number ratio (N/Si) of nitrogen to silicon in the area is 0.05 to 0.30,

wherein the gate electrode comprises at least one metal silicide selected from the group consisting of NiSi, Ni₂Si, Ni₃Si, NiSi₂, WSi₂, TiSi₂, VSi₂, CrSi₂, ZrSi₂, NbSi₂, MoSi₂, TaSi₂, CoSi, CoSi₂, PtSi, Pt₂Si, and Pd₂Si.

In another embodiment, there is provided a method of manufacturing a semiconductor device including a field effect transistor, the method comprising:

forming a gate insulating film material having a film thickness of 1 nm or more on a semiconductor layer, wherein at least an area of the gate insulating film material extending up to 1 nm from a side of the semiconductor layer in a thickness direction thereof comprises a silicon oxynitride film (SiON), an atom number ratio (O/Si) of oxygen to silicon in the area is 0.01 to 0.30, and an atom number ratio (N/Si) of nitrogen to silicon in the area is 0.05 to 0.30;

forming a polysilicon layer on the gate insulating film material;

patterning the gate insulating film material and the polysilicon layer to form a gate insulating film and a gate electrode material, respectively;

introducing a conductive material into the gate electrode material to form a gate electrode; and

forming a source area and a drain area in the semiconductor layer on both sides sandwiching the gate electrode.

The present invention can provide a gate insulating film offering a high relative dielectric constant, while reducing the interface level density of the interface between the silicon substrate and the gate insulating film. As a result, the present invention can provide an FET with a decrease in mobility minimized and a possible gate leakage current minimized.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a diagram illustrating the composition, in a depth direction, of a related gate insulating film composed of SiO₂;

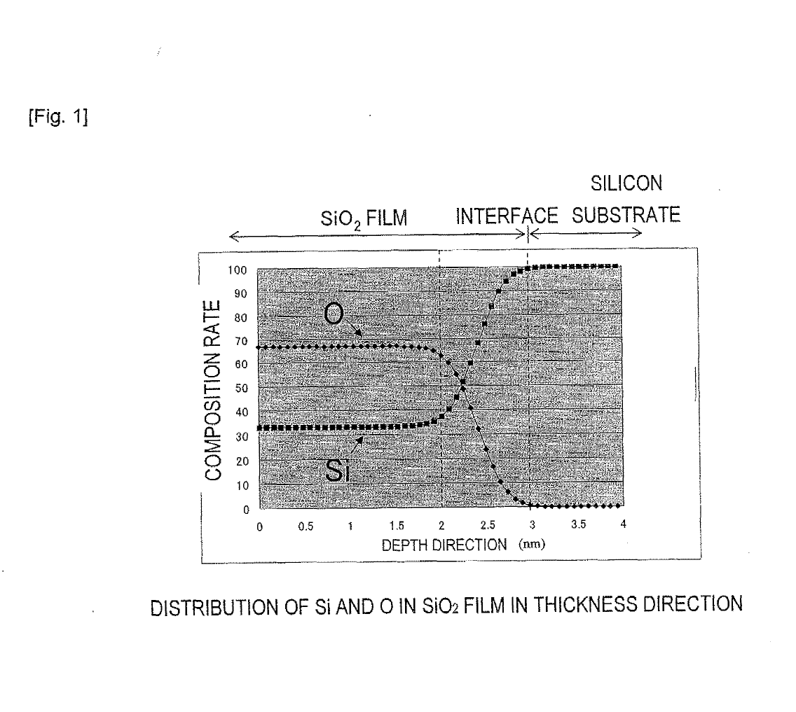

FIG. 2 is a diagram illustrating the composition, in the depth direction, of the related gate insulating film composed of SiO₂;

FIG. 3 is a diagram illustrating the composition, in a depth direction, of the related gate insulating film composed of SiON;

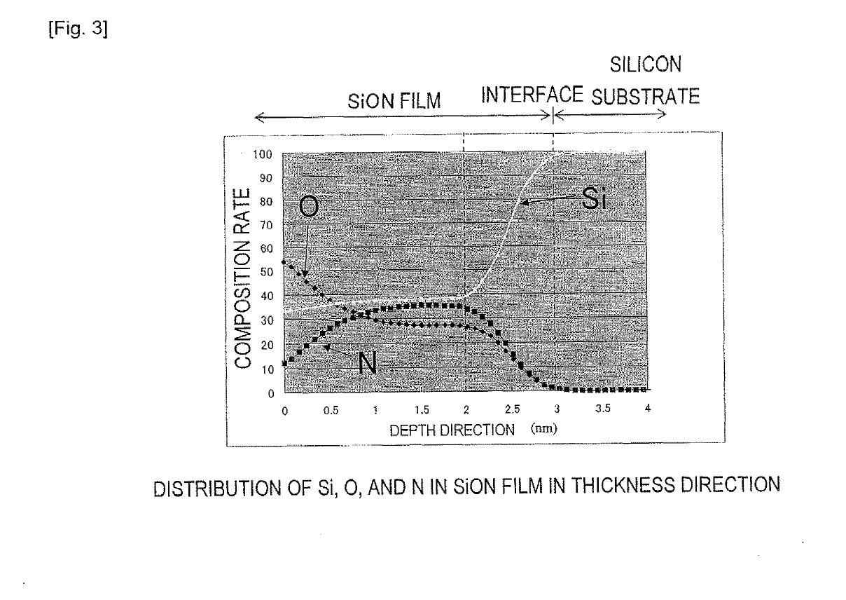

FIG. 4 is a diagram illustrating the composition, in the depth direction, of the related gate insulating film composed of SiON;

FIG. 5 is a diagram illustrating the composition, in the depth direction, of the related gate insulating film composed of SiON;

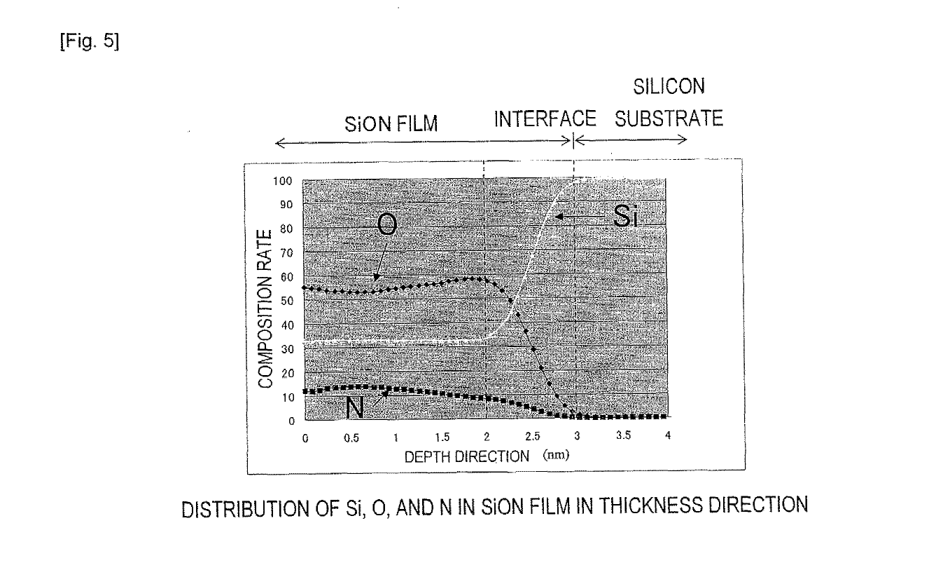

FIG. 6 is a diagram illustrating the composition, in the depth direction, of the related gate insulating film composed of SiON;

FIG. 7 is a diagram illustrating the composition, in a depth direction, of an example of a gate insulating film according to the present invention;

FIG. 8 is a diagram illustrating the composition, in the depth direction, of the example of the gate insulating film according to the present invention;

FIG. 9 is a diagram illustrating the relationship between the O/Si ratio and relative dielectric constant of the gate insulating film;

FIG. 10 is a diagram illustrating the relationship between the O/Si ratio and resistance value of the gate insulating film;

FIG. 11 is a diagram illustrating the relationship between the N/Si ratio and relative dielectric constant of the gate insulating film;

FIG. 12 is a diagram illustrating the relationship between the N/Si ratio and mobility of the gate insulating film;

FIG. 13 is a diagram illustrating the relationship between EOT and Jg;

FIG. 14 is a diagram illustrating an example of a semiconductor device according to the present invention;

FIG. 15 is a diagram illustrating an example of a part of the semiconductor device according to the present invention;

FIG. 16 is a diagram illustrating an example of a method of manufacturing a semiconductor device according to the present invention;

FIG. 17 is a diagram illustrating the example of the method of manufacturing the semiconductor device according to the present invention; and

FIG. 18 is a diagram illustrating the example of the method of manufacturing the semiconductor device according to the present invention.

In the drawings, numerals have the following meanings. 1: semiconductor layer, 2: isolation region, 3: gate insulating film, 4: gate electrode, 5: source/drain high-concentration region, 6: silicide layer, 7: sidewall insulating film, 8: source/drain contact region, 9: region having a thickness of 1 nm in a thickness direction from semiconductor layer side in the gate insulating film, 11: polysilicon layer, 12: photo resist, 13: gate insulating film material, 14: interlayer insulating film, 15: contact hole, 16: wiring

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### 1. Semiconductor Device

A semiconductor device comprises an FET (Field Effect Transistor) comprising a semiconductor layer, a gate electrode formed on the semiconductor layer, a gate insulating film formed between the semiconductor layer and the gate electrode, and a source area and a drain area formed on both sides sandwiching the gate electrode in the semiconductor layer.

The gate insulating film is thin and is 1 nm or more in thickness. The composition of a gate insulating film is measured by high resolution RBS (Rutherford Backscattering Spectrometry). Consequently, an area extending at least up to 1 nm from the semiconductor layer side in a thickness direction thereof is composed of a silicon oxynitride film (SiON). The atom number ratio (O/Si) of oxygen to silicon in the area is 0.01 to 0.30 and the atom number ratio (N/Si) of nitrogen to silicon in the area is 0.05 to 0.30.

The term “silicon oxynitride film (SiON)” as used herein refers to a film containing Si atoms, O atoms, and N atoms and does not indicate that the atom number ratio of Si atoms to O atoms to N atoms in the film is strictly 1:1:1. The term “silicon oxynitride film (SiON)” according to the present invention may contain atoms other than the Si, O, and N atoms as long as the O/Si ratio is 0.01 to 0.30 and the N/Si ratio is 0.05 to 0.30 as measured by high resolution RBS. For example, the silicon oxynitride film (SiON) according to the present invention includes an HfSiON film containing Hf atoms in addition to Si, O, and N atoms.

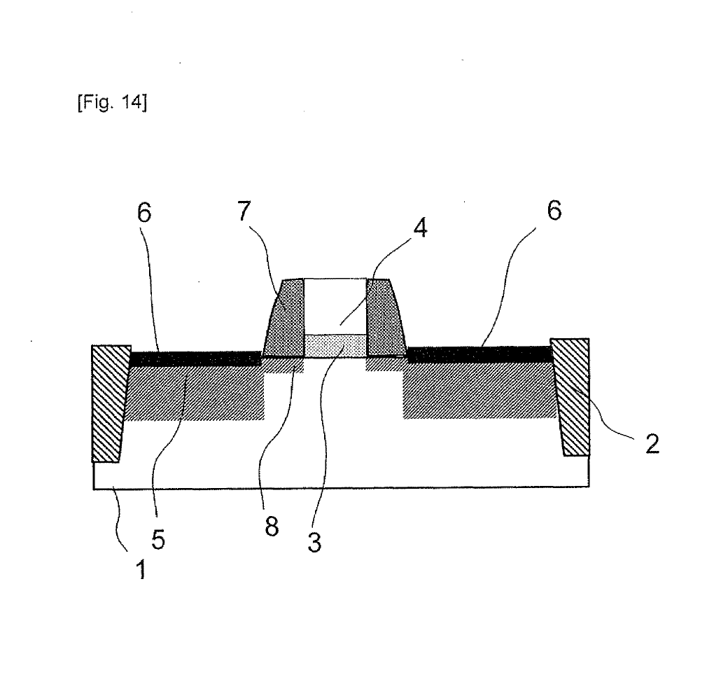

FIG. 14 illustrates an example of a semiconductor device according to the present invention. The semiconductor device includes a gate electrode 4 formed on a semiconductor layer 1. A gate insulating film 3 is formed between the semiconductor layer 1 and the gate electrode 4. A source contact area and a drain contact area 8 are formed on both sides sandwiching the gate electrode 4 in the semiconductor layer 1. Side wall insulating films 7 are provided on opposite side surfaces of the gate insulating film 3 and the gate electrode 4. A source high-concentration area and a drain high-concentration area 5 are formed on both sides sandwiching the gate electrode 4 and sidewalls 7 in the semiconductor layer 1. A silicide layer 6 is formed on each of the source high-concentration area and the drain high-concentration area 5 to be brought into contact with wiring. The source contact area and drain contact area 8 and the source high-concentration area and drain high-concentration area 5 constitute a source area and a drain area, respectively.

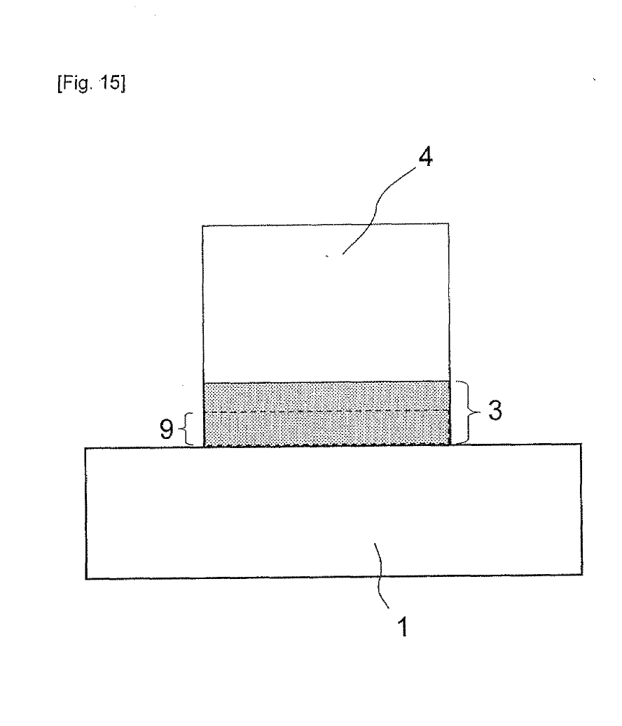

FIG. 15 is a partly enlarged diagram of the semiconductor layer 1, the gate insulating film 3, and the gate electrode 4. In the semiconductor device according to the present invention, the film thickness of the gate insulating film 3 is 1 nm or more. At least an area 9 of the gate insulating film 3 which extends up to 1 nm from the side of the semiconductor layer in the thickness direction thereof is composed of a silicon oxynitride film (SiON). The atom number ratio (O/Si) of oxygen to silicon in the area is 0.01 to 0.30, and the atom number ratio (N/Si) of nitrogen to silicon in the area is 0.05 to 0.30. Any part of this area 9 meets the relationship that the O/Si ratio is 0.01 to 0.30 and the N/Si ratio is 0.05 to 0.30.

In the semiconductor device according to the present invention, N, O, and Si exhibit the specific composition in the area very close to the semiconductor layer, the area extending up to 1 nm from the semiconductor layer in the thickness direction. This enables an effective reduction in the interface level density of the interface between the semiconductor layer and the gate insulating film, allowing an increase in the relative dielectric constant of the gate insulating film. As a result, a possible decrease in carrier mobility and a possible gate leakage current can be minimized. Moreover, these effects can be fully exerted even when the semiconductor device is miniaturized.

The effects of the relationship that the atom number ratio (O/Si) of the area 9 is 0.01 to 0.30 and the atom number ratio (N/Si) of the area 9 is 0.05 to 0.30 will be described below in detail.

### (Atom Number Ratio (O/Si) of Oxygen to Silicon is 0.01 to 0.30)

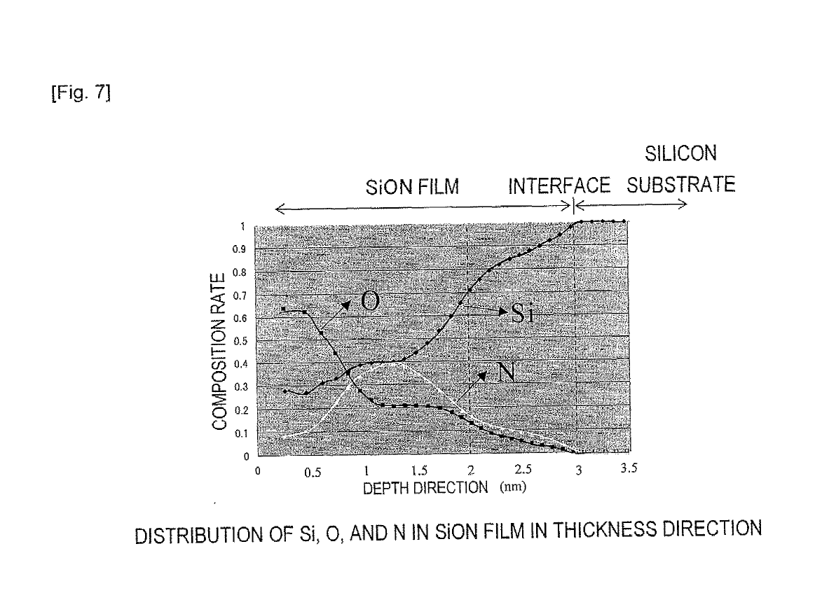

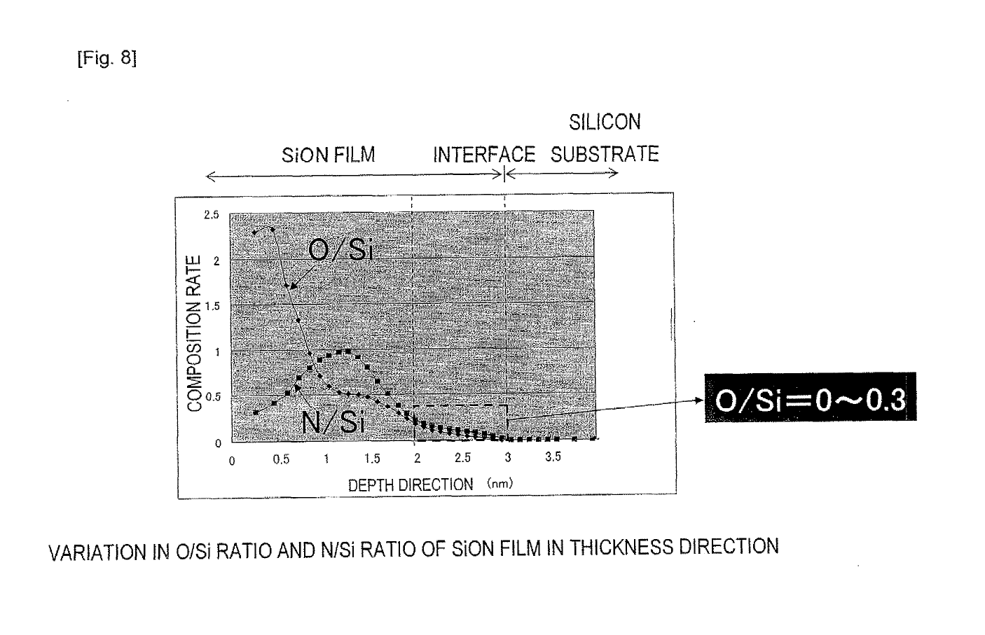

FIG. 7 illustrates the distribution of the composition, in the depth direction, of the gate insulating film containing SiON according to the present invention. FIG. 8 illustrates the N/Si ratio and O/Si ratio of the gate insulating film. In FIGS. 7 and 8, 0 nm on the axis of abscissa indicates a gate electrode-side surface of the gate insulating film side, and 3 nm on the axis of abscissa indicates the interface between the gate insulating film and the semiconductor layer.

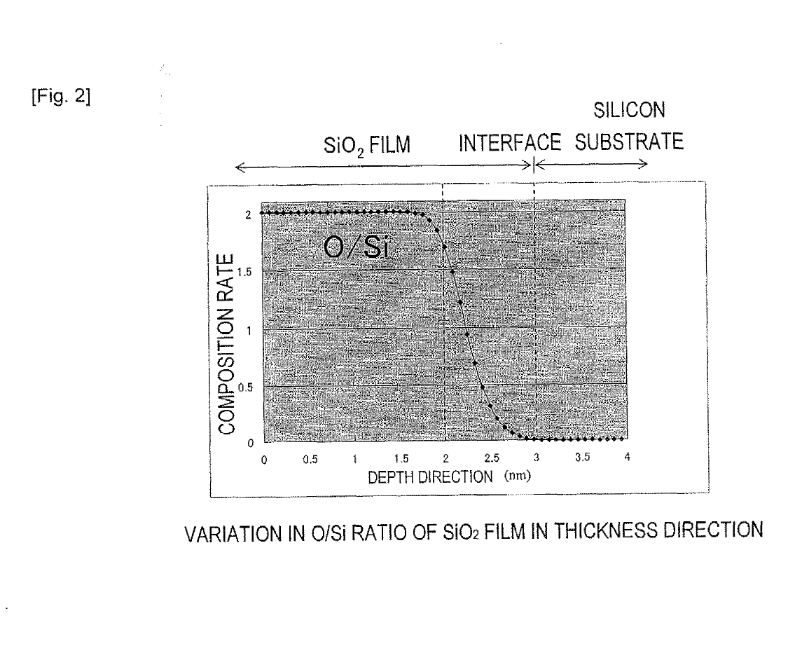

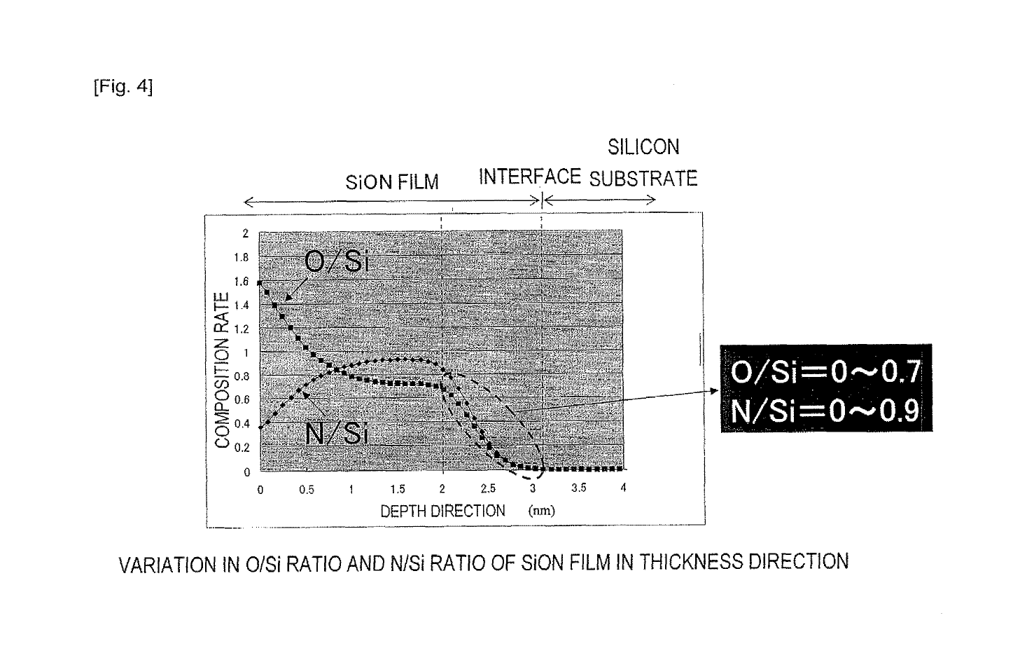

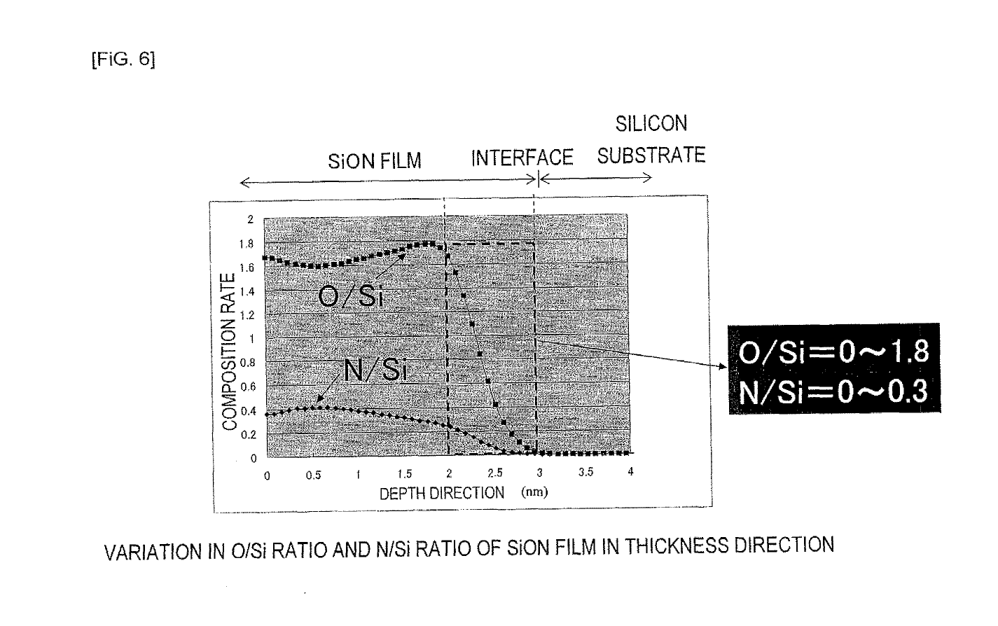

As is apparent from a comparison of FIGS. 2, 4, and 6 with FIGS. 7 and 8, with the O/Si ratio according to the present invention, the O/Si ratio in the vicinity of the Si substrate interface (the area corresponding to 2 to 3 nm on the axis of abscissa) can be set to 0.01 to 0.3. This enables an increase in Si concentration compared to the related O/Si ratio in the vicinity of the Si substrate interface. Increasing the Si concentration as in the case of the present invention enables an increase in the relative dielectric constant of the gate insulating film.

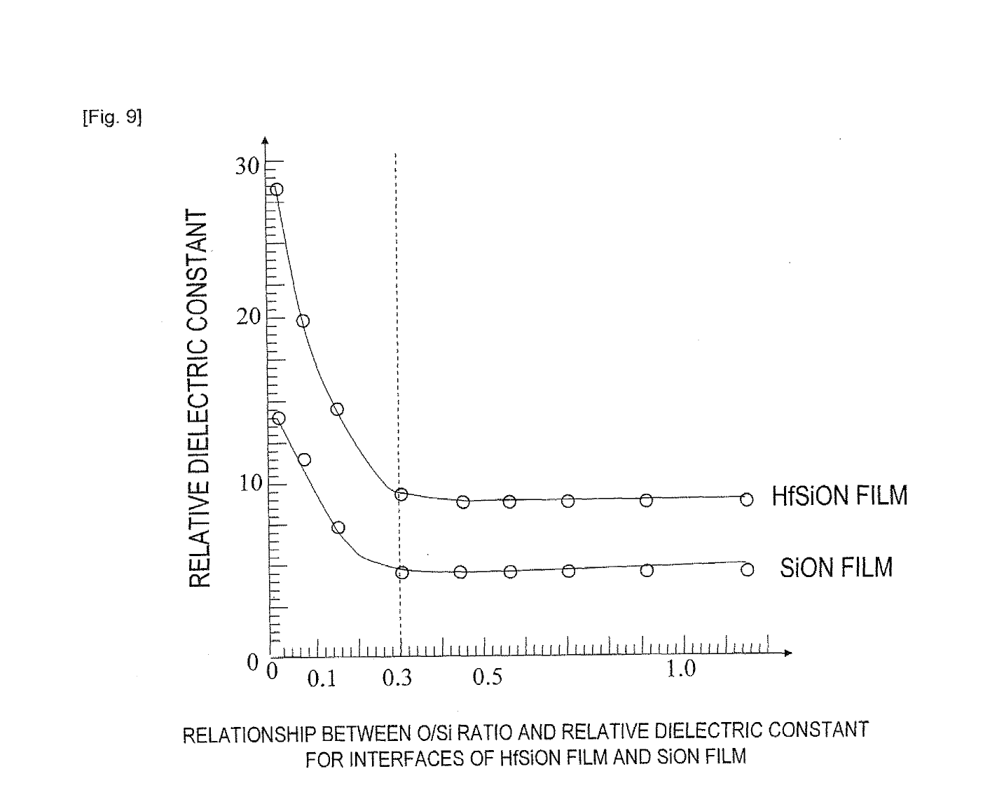

FIG. 9 is a diagram illustrating the relationship between the relative dielectric constant and the O/Si ratio of the interface in the SiON film and the HfSiON film. The relative dielectric constant in FIG. 9 was measured as follows. First, an Agilent B1500A Semiconductor Device Analyzer was used to calculate EOT (electric film thickness) of each of the SiON film and HfSiON film by C—V measurement. Then, a TEM (Transmission Electron Microscope) was used to determine the physical film thickness of each of the SiON film and the HfSiON film. On the basis of the measurement results of the EOT (electric film thickness) and the physical film thickness, the relative dielectric constant was calculated.

FIG. 9 illustrates that for both the SiON film and the HfSiON film, the relative dielectric constant is increased by setting the ratio of oxygen to silicon (O/Si) to at 0.30 or less. This indicates that the relative dielectric constant can be increased by setting the ratio of oxygen to silicon (O/Si) in the vicinity of the Si substrate interface to at 0.30 or less. This is considered that since the relative dielectric constant of Si is 15, the increased Si concentration of the Si substrate interface increases the relative dielectric constant of each of the SiON film and the HfSiON film.

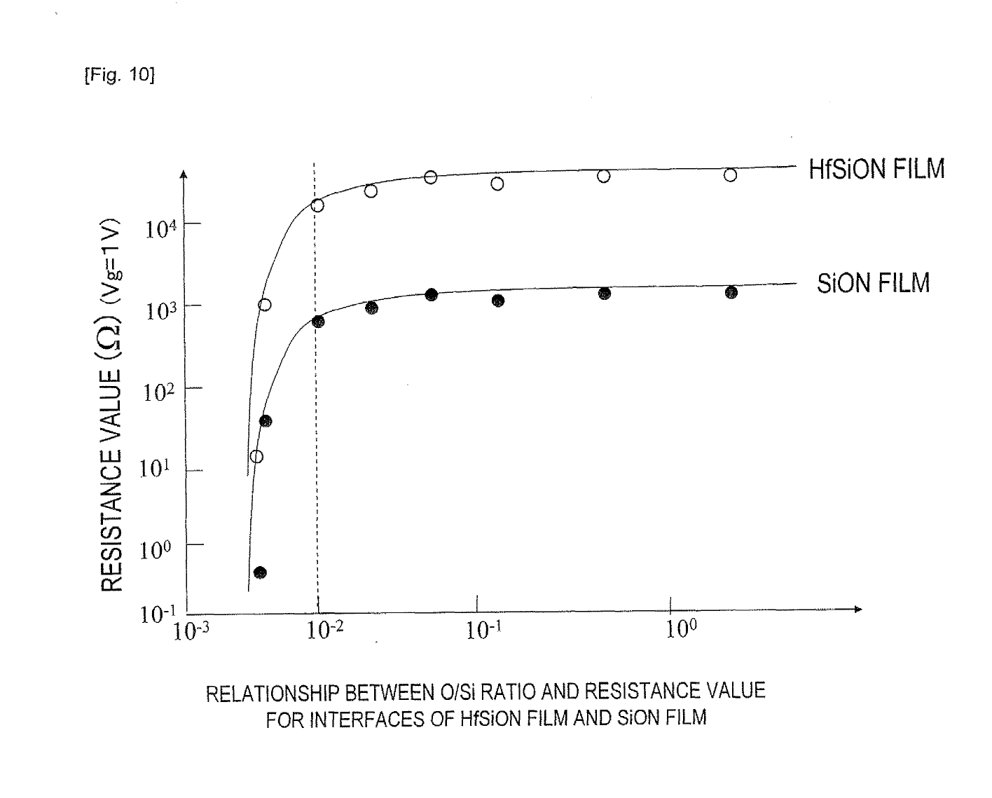

FIG. 10 illustrates the resistance values of the gate insulating films composed of the SiON film and the HfSiON film, respectively. The resistance values were measure using the Agilent B1500A Semiconductor Device Analyzer.

FIG. 10 indicates that the resistance value of the gate insulating film decreases rapidly if the ratio of oxygen to silicon (O/Si) in the area is less than 0.01. This is because when the Si concentration in the interface between the gate insulating film and the semiconductor layer is too high compared to the O concentration, the insulating property is prevented from being maintained because Si is a semiconductor.

FIG. 10 thus indicates that to inhibit a possible leakage current, the O/Si ratio of the interface between the gate insulating film and the semiconductor layer (the area extending up to 1 nm from the semiconductor layer side of the gate insulating film in the thickness direction) needs to be within the range of 0.01 to 0.3, corresponding to the range involving a high relative dielectric constant and a high resistance value.

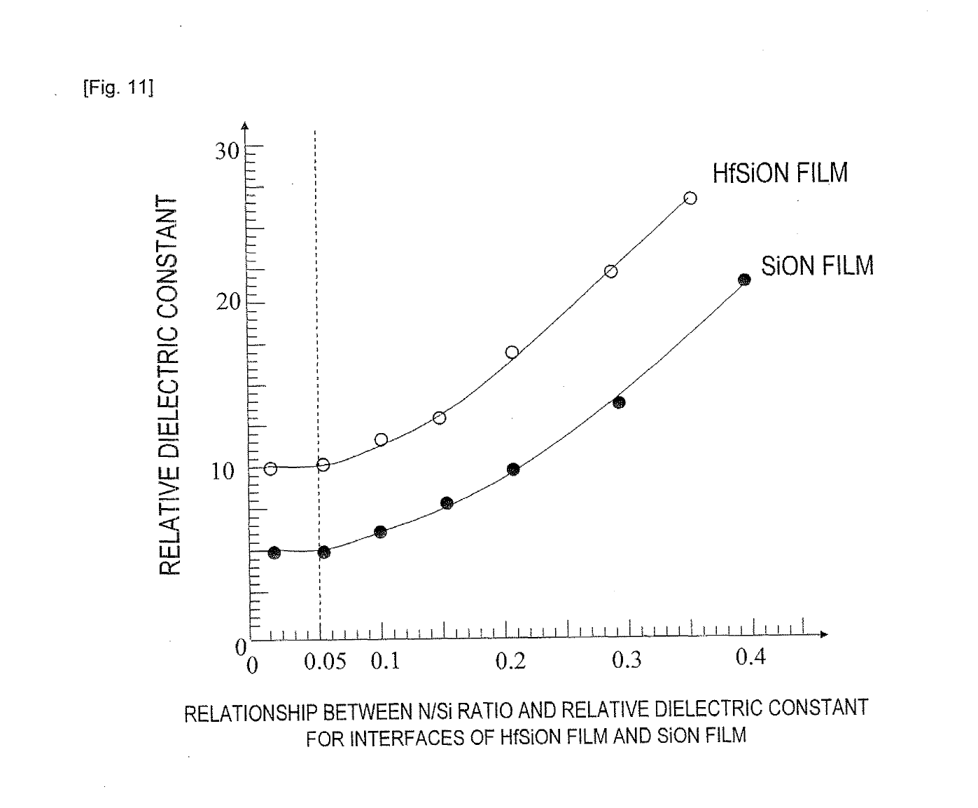

In FIG. 10, the HfSiON film offers a higher resistance value than the SiON film at the same electric film thickness (EOT) because the HfSiON film has the higher dielectric electric constant than the SiON film and exhibits a larger effective physical film thickness than the SiON film as shown in FIGS. 9 and 11.

### (Atomic Number Ratio of Nitrogen to Silicon (N/Si) is 0.05 to 0.30)

FIG. 11 shows the relative dielectric constant of each of the SiON film and the HfSiON film with respect to the N/Si ratio. The relative dielectric constant was measured by a method similar to that shown in FIG. 9. FIG. 11 illustrates that in the vicinity of the interface between the gate insulating film and the Si substrate, an N/Si ratio of 0.05 or more increases the relative dielectric constant. This is expected to be because an Si—N bond increased the dielectric constant.

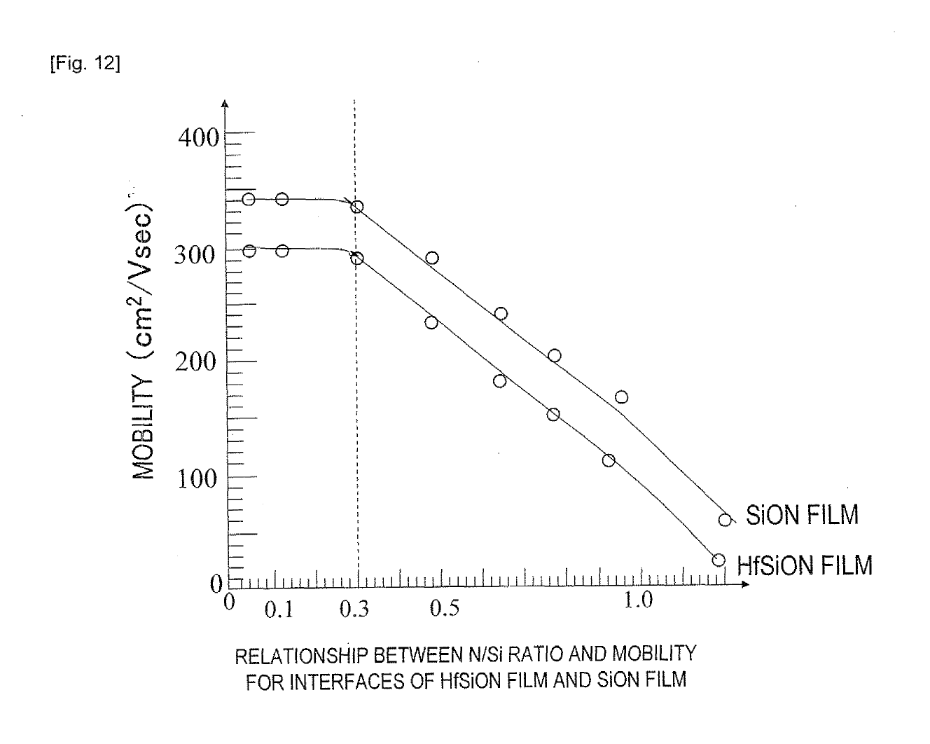

Furthermore, the nitrogen in the vicinity of the interface between the gate insulating film and the Si substrate is expected to increase the interface level density to reduce the mobility. This is illustrated in FIG. 12. That is, FIG. 12 is a diagram illustrating the relationship between the mobility and the N/Si ratio in the vicinity of the interface in the gate insulating film for the gate insulating films composed of each of the SiON film and the HfSiON film. The mobility was measured using the Agilent B1500A Semiconductor Device Analyzer.

FIG. 12 illustrates that the mobility decreases significantly when the N/Si ratio in the vicinity of the interface between the gate insulating film and the Si substrate is higher than 0.3. The reason is considered because the interface level density was increased by the increased concentration of the nitrogen in the vicinity of the interface between the gate insulating film and the semiconductor layer. This in turn indicates that to increase the relative dielectric constant to inhibit a possible decrease in mobility, the N/Si ratio needs to be within the range of 0.05 to 0.3.

The above-described results indicate that to obtain a gate insulating film with a high relative dielectric constant with the interface level density of the interface between the silicon substrate and the gate insulating film reduced, the area extending up to 1 nm from the side of the semiconductor layer in the thickness direction thereof needs to meet the following conditions.
(a) The gate insulating film is composed of a silicon oxynitride film (SiON).
(b) The atom number ratio (O/Si) of oxygen to silicon is set to 0.01 to 0.30.
(c) The atom number ratio (N/Si) of nitrogen to silicon is set to 0.05 to 0.30.

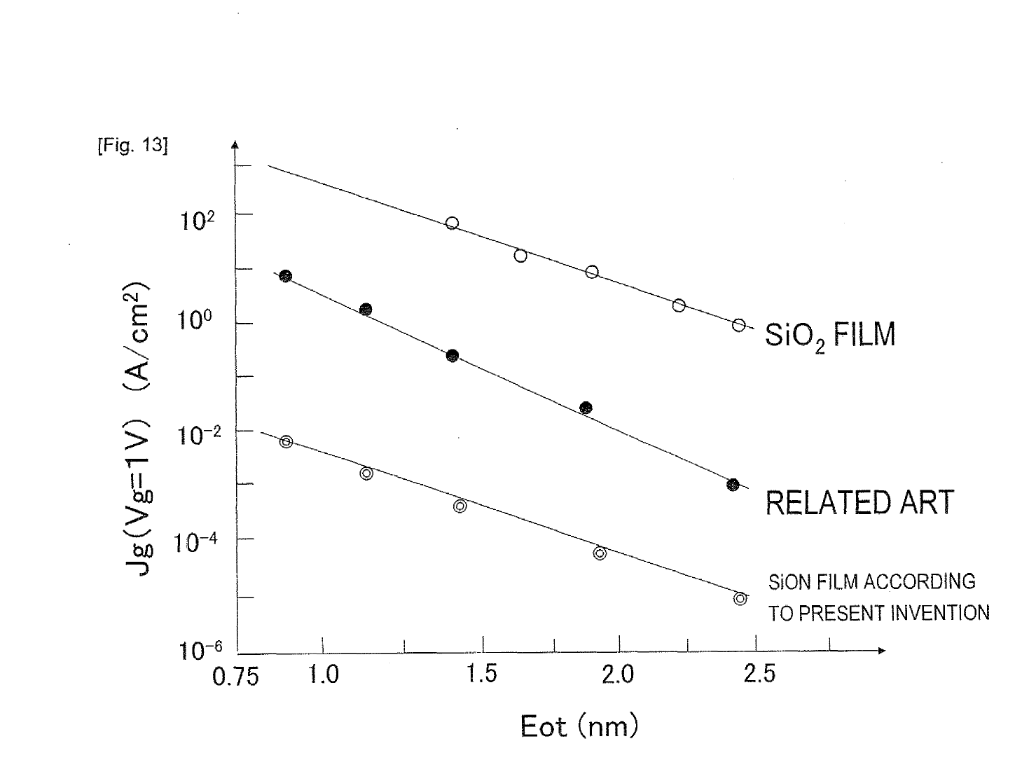

Furthermore, Jg (leakage current) can be reduced by configuring the area extending up to 1 nm from the side of the semiconductor layer in the thickness direction thereof, as described above. FIG. 13 illustrates the results of the configuration and the relationship between Jg and EOT in the SiON film. Jg (Vg) denotes the value of a leakage current from the gate insulating film, and EOT denotes the electric film thickness. Measurements were performed using the Agilent B1500A Semiconductor Device Analyzer.

The results in FIG. 13 indicate that the FET using the gate insulating film composed of the SiON film according to the present invention exhibits a smaller Jg than the related FET and an FET using the gate insulating film composed of the SiO₂ film and allows a possible leakage current to be inhibited even with a reduced film thickness. This is expected to be because the effective physical film thickness was successfully increased by increasing the relative dielectric constant of the gate insulating film.

The FET according to the present invention may be an nFET or a pFET. Regardless of the type of the FET, the characteristics (a) to (c) of the gate insulating film enable effective improvement of the mobility and prevention of a possible leakage current.

The film thickness of the gate insulating film is preferably 1 to 3 nm. The film thickness of the gate insulating film within this range results in a miniaturized FET with the mobility reduced and a possible gate leakage current inhibited.

The component of the gate electrode is not particularly limited. For example, a single layer film of polycrystalline silicon, a single layer film of metal silicide or the like can be used. Preferably, a gate electrode composed of metal silicide is used. Thus, the use of the gate electrode composed of the metal silicide can effectively prevent the gate electrode from being depleted.

The metal silicide may be a silicide of at least one type of element selected from a group consisting of Ni, Cr, Cu, Ir, Rh, Ti, Zr, Hr, V, Ta, Nb, Mo, and W. Specific examples of the silicide include NiSi, Ni₂Si, Ni₃Si, NiSi₂, WSi₂, TiSi₂, VSi₂, CrSi₂, ZrSi₂, NbSi₂, MoSi₂, TaSi₂, CoSi, CoSi₂, PtSi, Pt₂Si, and Pd₂Si.

Furthermore, the present invention is not particularly limited to the composition of the area A extending exceeding 1 nm from the side of the semiconductor layer in the gate insulating film in the thickness direction thereof. Additionally, the area A may be composed of a silicon oxynitride film (SiON), the atom number ratio (O/Si) of oxygen to silicon in the area A may be 0.01 to 0.30, and the atom number ratio (N/Si) of nitrogen to silicon in the area A may be 0.05 to 0.30. For example, the composition of the area A may be silicon oxide (SiO₂), silicon nitride (Si₃N₄), hafnium (HF), or the like. Alternatively, the gate insulating film may be metal oxide, metal silicate, a high-dielectric-constant insulating film composed of the metal oxide or metal silicate into which nitrogen is introduced, or the like. The “high-dielectric-constant insulating film” refers to an insulating film offering a higher relative dielectric constant than SiO₂, which is commonly used in the FET as a gate insulting film (the relative dielectric constant of SiO₂ is about 3.6). Typically, the relative dielectric constant of the high-dielectric-constant insulating film is several tens to several thousands. Examples of the high-dielectric-constant insulating film include HfSiO, HfSiON, HfZrSiO, HfZrSiON, ZrSiO, ZrSiON, HfAlO, HfAlON, HfZrAlO, HfZrAlON, ZrAlO, and ZrAlON.

An n-type impurity element is doped into the source and drain areas of the nFET. A p-type impurity element is doped into the source and drain areas of the pFET. If an Si layer is used as the semiconductor layer, B may be used as the p-type impurity element and P, As, Sb, or the like may be used as the n-type impurity element. The concentration of the impurity element in the source and drain areas is typically 1×10¹⁹ to 1×10²¹ cm⁻³.

### 2. Method of Manufacturing the Semiconductor Device

A method of manufacturing a semiconductor device comprises:

a step of forming a gate insulating film material with a film thickness of 1 nm or more on a semiconductor layer, at least an area of the gate insulating film material which extends up to 1 nm from a side of the semiconductor layer in a thickness direction thereof comprising a silicon oxynitride film (SiON), an atom number ratio (O/Si) of oxygen to silicon in the area being 0.01 to 0.30, an atom number ratio (N/Si) of nitrogen to silicon in the area being 0.05 to 0.30;

a step of forming a polysilicon layer on the gate insulating film material;

a step of patterning the gate insulating film material and the polysilicon layer to form a gate insulating film and a gate electrode material, respectively;

a step of forming a gate electrode by introducing a conductive material into the gate electrode material; and

a step of forming a source area and a drain area on both sides sandwiching the gate electrode in the semiconductor layer.

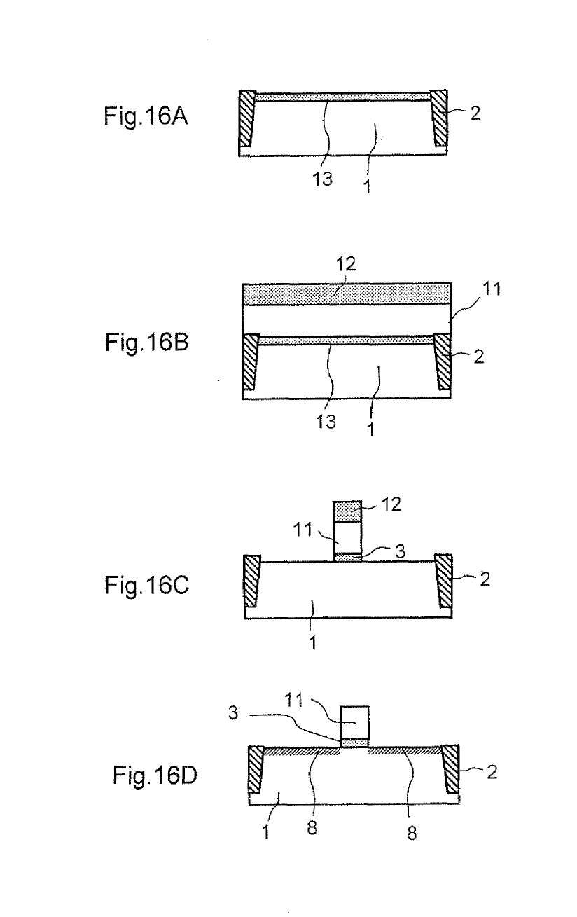

FIGS. 16 to 18 show an example of the method of manufacturing the semiconductor device according to the present invention. First, an isolation region 2 such as STI (Shallow Trench Isolation) is buried and formed in a p-type silicon semiconductor layer 1. Subsequently, channel ion injection with boron or the like is performed on an exposed surface of the silicon semiconductor layer 1.

Then, a gate insulating film material 13 is deposited on the silicon semiconductor layer 1 (FIG. 16A). The gate insulating film material 13 is formed such that the film thickness of the material 13 is 1 nm or more and at least an area of the material 13 extending up to 1 nm from the side of the semiconductor layer in the thickness direction thereof is composed of a silicon oxynitride film (SiON) and such that the atom number ratio (O/Si) of oxygen to silicon in the area is 0.01 to 0.30 and the atom number ratio (N/Si) of nitrogen to silicon in the area is 0.05 to 0.30 as described below.

Then, a polysilicon layer (PolySi) 11 is formed on the gate insulating film material 13. Instead of the polysilicon layer 11, a polysilicon germanium (polySiGe) film or a metal material may be used.

Subsequently, a photo resist 12 is coated on the polysilicon layer 11 (FIG. 16B) and patterned so as to be shaped into the gate electrode. The gate insulating film material 13 and the polysilicon layer 11 are then patterned using the photo resist 12 as a mask to form the gate insulating film 3 and the gate electrode material 11 (FIG. 16C).

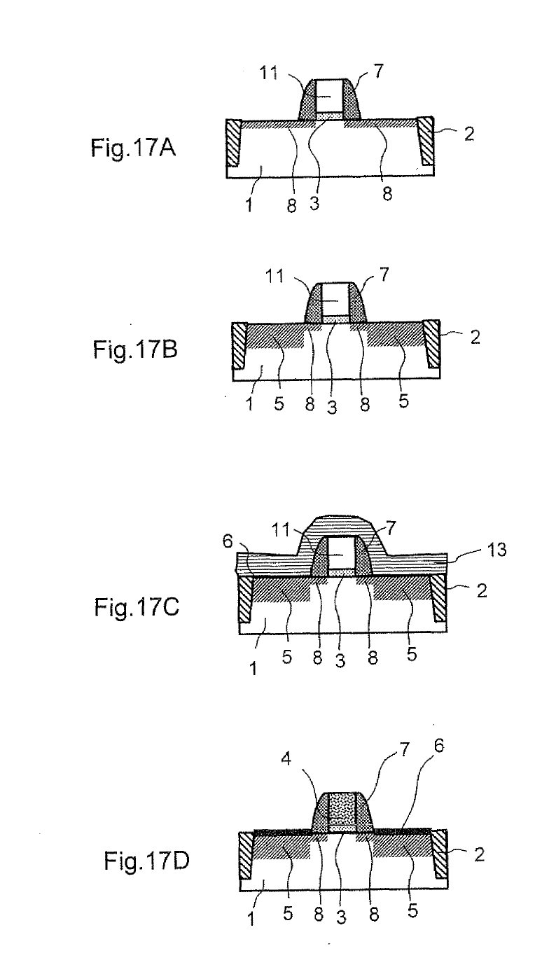

Subsequently, the photo resist 12 is removed. Arsenic ions or the like are injected into a surface area of the silicon semiconductor layer 1 to form the n-type source and drain contact areas (extension areas) 8 (FIG. 16D). A silicon oxide film (SiO₂) is then deposited by a CVD method so as to cover the entire surface of the silicon semiconductor layer 1 with the gate electrode. The silicon oxide film is subsequently etched back by, for example, RIE (Reactive Ion Etching) to form sidewall insulating films 7 on side surfaces of the gate electrode material 11 (FIG. 17A).

Subsequently, phosphorous, arsenic ions or the like are injected into a surface area of the silicon semiconductor layer 1 using the sidewall insulating films 7 as a mask to form the n-type source and drain high-concentration areas 5 (FIG. 17B). The source and drain contact areas 8 and the source and drain high-concentration areas 5 form the n-type source and drain areas, respectively.

Then, the metal film 13 such as cobalt (Co) or nickel (Ni) is deposited on the entire surface of the resulting structure by a sputtering method or the like (FIG. 17C). Thermal treatment is then performed to change the metal film deposited on the surface of the structure and the surface of the gate electrode material 11 into the metal silicide film 4 such as CoSi₂ or NiSi, forming the gate electrode 4. At the same time, the silicide film 6 is formed on the source and drain areas 5. The metal film deposited on the sidewall insulating film 7 and the isolation region 2, which is not changed into silicide, is removed (FIG. 17D).

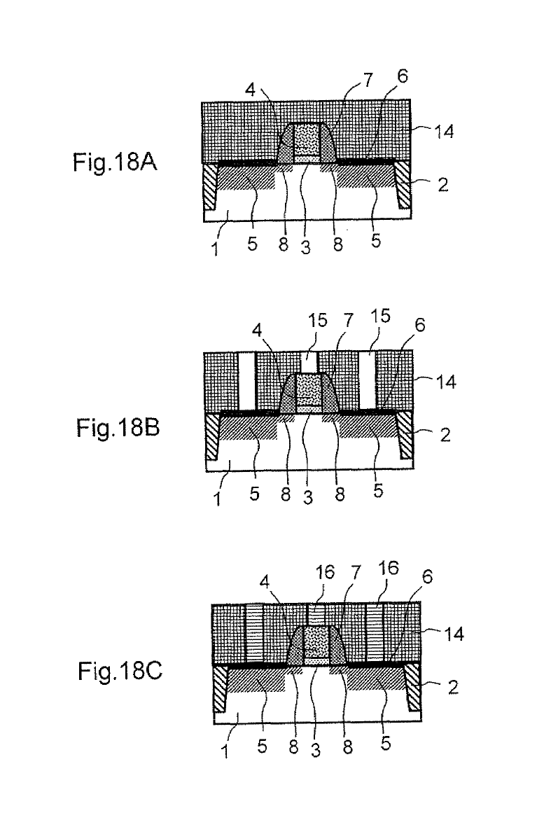

Then, an interlayer insulating film 14 made up of a silicon oxide film such as BPSG is deposited all over the surface of the resulting structure by a CVD method or the like (FIG. 18A). The interlayer insulating film 14 is etched to form contact holes 15 so as to expose the silicide film 6 and the gate electrode 4 on the source and drain areas 5 by an RIE method or the like (FIG. 18B). Then, a metal film such as copper or aluminum is formed all over a surface of the interlayer insulating film 14. A CMP process is then carried out to form wirings 16 electrically connected to the silicide film 6 and the gate electrode 4 on the source and drain areas 5 via the contact holes (FIG. 18C). Moreover, a passivation film and the like are formed on the semiconductor substrate to complete the semiconductor device according to the present invention.

According to the method of manufacturing the semiconductor device according to the present invention, in the step of forming the gate insulating film material, the film thickness of the gate insulating film material is at 1 nm or more, and at least an area of the material extending up to 1 nm from the side of the semiconductor layer in the thickness direction thereof is composed of a silicon oxynitride film (SiON) and the atom number ratio (O/Si) of oxygen to silicon in the area is 0.01 to 0.30 and the atom number ratio (N/Si) of nitrogen to silicon in the area is 0.05 to 0.30.

In the step of forming the gate insulating film material, the gate insulating film material is preferably formed such that the film thickness of the material is 1 to 3 nm. Forming such a gate insulating film material with a small film thickness allows a miniaturized FET to be stably manufactured.

Furthermore, in the step of forming the gate electrode, for example, the gate electrode is obtained by doping impurities (conductive material) into the gate electrode material in the polysilicon layer and doping metal (conductive material) into the gate electrode material in the polysilicon layer for reaction to form metal silicide.

An example of the specific step of forming the gate insulating film material forming is illustrated below.

### [Step of Forming the Gate Insulating Film Material]

In an example of the step of forming the gate insulating film material, a gate insulating film material with a two-layer structure is formed which comprises a base film and also an upper layer film on the base film. The total film thickness of the base film and the upper layer film is 1 nm or more. The base film and the upper layer film are composed of a silicon oxynitride film (SiON). The atom number ratio (O/Si) of oxygen to silicon in the layers is 0.01 to 0.30 and the atom number ratio (N/Si) of nitrogen to silicon in the layers is 0.05 to 0.30. (1) A step of forming the base film and (2) a step of forming the upper layer film are illustrated below.

### (1) Step of Forming the Base Film

First, the gate insulating film material of the SiON film is formed by an ALD method (Atomic Layer Deposition Method). Specifically, an Si film is deposited and then oxidized with O₃ to form an SiOₓ film. The SiOₓ film is subsequently nitrided with plasma NH₃ to form the base film. Si growth time, O₃ oxidization time, plasma NH₃ nitriding time, and plasma power can be appropriately adjusted according to the film composition.

A silicon source gas is not particularly limited but may be Si₂H₆, SiH₄, Si(MMP)₄((Tetrakis 1-Methoxy-2-Methyl-2-Propoxy Silane)Si[OC(CH₃)₂CH₂OCH₃]₄), Si(DMAP)((Tetrakis 1-(N,N-dimethylamino)-2Propoxy Silane)Si[OCH(CH₃)CH₂N(CH₃)₂]₄), TDMASi(Tetrakis diemethyl amido Silane)Si[N(CH₃)₂]₄), or the like. Among these gases, Si₂He is preferably used as a silicon source.

An example of SiON film formation conditions for the step of forming the gate insulating film will be described below. First, an Si material gas is fed onto a semiconductor substrate at a substrate temperature of 550° C. for 20 ms to 1 s. Subsequently, purging is sufficiently performed, an O₃ gas is fed (up to one second), and purging is performed again to produce an SiOₓ film. These steps result in deposition of the SiOₓ film to a film thickness of about 0.1 nm. These steps correspond to one cycle.

The cycle is repeated 5 to 30 times to form the film, which is then nitrided with plasma NH₃. Preferable conditions for the plasma NH₃ nitriding include a plasma power of 0.3 kW and an NH₃ plasma treatment time of less than 10 sec.

### (2) Step of Forming the Upper Layer Film

Then, the upper layer film is formed on the base film formed in the (1) “step of forming the base film”. Examples of the upper layer film include an HfSiON film and an SiON film. (a) a step of forming a hafnium-containing silicon oxide film (HfSiON film) and (b) a step of forming an SiON film are illustrated below.

### (a) Step of Forming a Hafnium-Containing Silicon Oxide Film (HfSiON Film)

As a method of depositing the HfSiON film, MOCVD or ALD is preferably used, and MOCVD is more preferably used. A reaction gas that can be used with the MOCVD method is, for example, a mixture of a silicon source gas and a hafnium source gas such as those described below.

Examples of the silicon source gas include Si₂H₆, SiH₄, Si(MMP)₄((Tetrakis 1-Methoxy-2-Methyl-2-Propoxy Silane)Si[OC(CH₃)₂CH₂OCH₃]₄), Si(DMAP)((Tetrakis 1-(N,N-dimethylamino)-2Propoxy Silane)Si[OCH(CH₃)CH₂N(CH₃)₂]₄), and TDMASi(Tetrakis diemethyl amido Silane)Si[N(CH₃)₂]₄).

Examples of the hafnium source gas include THB((Hafnium tetra-t-butoxide)Hf[OC(CH₃)₃]₄), TDEAH((Tetrakis diethylamido hafnium)C₁₆H₄₀N₄Hf), TDMAH((Tetrakis dimethylamino hafnium)C₈H₂₄N₄Hf), Hf(MMP)₄((Tetrakis, 1-Methoxy-2-methyl-2-propoxy hafnium)Hf[OC(CH₃)₂CH₂OCH₃]₄), and Hf(NO₃)₄.

The combination of the silicon source gas and the hafnium source gas is not particularly limited; any of the above-described silicon source gases can be combined with any of the above-described hafnium source gases However, preferably, Si₂H₆ is used as a silicon source gas, and THB is used as a hafnium source gas.

The flow ratio of the silicon source gas to the hafnium source gas is not particularly limited. However, the flow ratio is preferably adjusted such that the (Si/(Hf+Si)) ratio in the hafnium-containing silicon oxide is within the range from 0 to 50 atom percents and more preferably from 30 to 40 atom percents. The atom number ratio of the mixed gas is adjusted by the gas flow rates of the material gases. These reaction gases may contain a carrier gas such as an oxidized gas such as oxygen. The substrate temperature may be set to, for example, about 300° C.

Then, the hafnium-containing silicon oxide film formed is nitrided in an ammonia atmosphere or a plasma atmosphere. The nitriding in the ammonia atmosphere is performed under treatment conditions including 700° C. and 30 minutes.

### (b) Step of Forming an SiON Film

As a method of depositing an SiON film, MOCVD or ALD is preferably used, and MOCVD is more preferably used. A reaction gas that can be used with the MOCVD method may contain a silicon source gas such as those described below.

Examples of the silicon source gas include Si₂H₆, SiH₄, Si(MMP)₄((Tetrakis 1-Methoxy-2-Methyl-2-Propoxy Silane)Si[OC(CH₃)₂CH₂OCH₃]₄), Si(DMAP)((Tetrakis 1-(N,N-dimethylamino)-2Propoxy Silane)Si[OCH(CH₃)CH₂N(CH₃)₂]₄), and TDMASi(Tetrakis diemethyl amido Silane)Si[N(CH₃)₂]₄).

The silicon source gas is not particularly limited, but Si₂H₆ is preferably used. The above-described reaction gases may contain a carrier gas such as an oxidized gas such as oxygen. The substrate temperature may be set to, for example, about 300° C.

Then, the silicon oxide film formed as described above is nitrided in an ammonia atmosphere or a plasma atmosphere. The nitriding in the ammonia atmosphere is performed under treatment conditions including 700° C. and 30 minutes.

### [Evaluation of the Gate Insulating Film]

(a) the hafnium-containing silicon oxide film (HfSiON film), forming the base film and upper layer film, and (b) the gate insulting film of the SiON film formed as described above can be evaluated as described below.

### 1. High Resolution RBS (Rutherford Backscattering Spectrometry) Evaluation (the Evaluation of the Composition)

### (Measurement Conditions)

Incident ion energy: 300 keV, ion species: He⁺, incident angle: 45 degrees to a norm perpendicular to a plane direction of a sample, current applied to the sample: 25 nA, irradiation amount: 90 μC

### (Measurement Method)

The sample was irradiated with He⁺ with an incident energy of 300 keV at an angle of 45 degrees to the norm perpendicular to the plane direction of the sample. The scattered He⁺ was detected at a set scattering angle by a polarized magnetic field energy analyzer.

### (Analysis Method)

(1) On the basis of a middle point of a high energy-side edge for oxygen, a channel for the axis of abscissa is converted into scattered ion energy.
(2) A system background is subtracted from the scattered ion energy.
(3) The background of oxygen is subtracted from the scattered ion energy by a straight line.
(4) The background of nitrogen is estimated on the basis of a signal from a sample containing no nitrogen and subtracted.
(5) A concentration profile in the depth direction is determined by simulation fitting and subtracted.

### 2. Evaluation of the Relative Dielectric Constant

### (Measurement Method)

A TEG was produced as described below, and the EOT (electric film thickness) of the sample was determined by C—V measurement. The physical film thickness of the sample was also determined using the TEM (Transmission Electron Microscope). Then, the relative dielectric constant was calculated on the basis of the results of the measured EOT and physical film thickness.

### 3. Evaluation of a Possible Leakage Current and the Mobility

### (Measurement Method)

The TEG produced as described above was evaluated.

### (Method of Producing the TEG)

The TEG (Test Element Group) was produced as described above in connection with the method of manufacturing the semiconductor device.

It is apparent that the present invention is not limited to the above embodiments, but may be modified and changed without departing from the scope and spirit of the invention.

What is claimed is:

1. A semiconductor device including a field effect transistor comprising:
a semiconductor layer;
a gate electrode formed over the semiconductor layer;
a gate insulating film having a film thickness of 1 nm or more formed between the semiconductor layer and the gate electrode; and
a source area and a drain area formed in the semiconductor layer on both sides sandwiching the gate electrode,
wherein at least an area of the gate insulating film extending up to 1 nm from a side of the semiconductor layer in a thickness direction thereof comprises a silicon oxynitride film (SiON),
an atom number ratio (O/Si) of oxygen to silicon in the area is 0.01 to 0.30, and
an atom number ratio (N/Si) of nitrogen to silicon in the area is 0.05 to 0.30.

2. The semiconductor device according to claim 1, wherein the film thickness of the gate insulating film is 1 to 3 nm.

3. The semiconductor device according to claim 1, wherein the gate electrode comprises metal silicide.

4. A semiconductor device including a planar-type field effect transistor comprising a gate insulating film formed on a semiconductor layer,
wherein at least an area of the gate insulating film extending up to 1 nm from a side of the semiconductor layer in a thickness direction thereof comprises a silicon oxynitride film (SiON),
an atom number ratio (O/Si) of oxygen to silicon in the area is 0.01 to 0.30, and
an atom number ratio (N/Si) of nitrogen to silicon in the area is 0.05 to 0.30.

5. The semiconductor device according to claim 4, wherein the film thickness of the gate insulating film is 1 to 3 nm.

6. The semiconductor device according to claim 4, wherein the gate electrode comprises metal silicide.

7. A semiconductor device including a planar-type field effect transistor comprising:
a gate insulating film formed on a semiconductor layer; and
a gate electrode formed on the gate insulating film,
wherein at least an area of the gate insulating film extending up to 1 nm from a side of the semiconductor layer in a thickness direction thereof comprises an HfSiON film,
an atom number ratio (O/Si) of oxygen to silicon in the area is 0.01 to 0.30, and
an atom number ratio (N/Si) of nitrogen to silicon in the area is 0.05 to 0.30,
wherein the gate electrode comprises at least one metal silicide selected from the group consisting of NiSi, Ni₂Si, Ni₃Si, NiSi₂, WSi₂, TiSi₂, VSi₂, CrSi₂, ZrSi₂, NbSi₂, MoSi₂, TaSi₂, CoSi, CoSi₂, PtSi, Pt₂Si, and Pd₂Si.

8. The semiconductor device according to claim 7, wherein the film thickness of the gate insulating film is 1 to 3 nm.

9. A method of manufacturing a semiconductor device including a field effect transistor, the method comprising:
forming a gate insulating film material having a film thickness of 1 nm or more on a semiconductor layer, wherein at least an area of the gate insulating film material extending up to 1 nm from a side of the semiconductor layer in a thickness direction thereof comprises a silicon oxynitride film (SiON), an atom number ratio (O/Si) of oxygen to silicon in the area is 0.01 to 0.30, and an atom number ratio (N/Si) of nitrogen to silicon in the area is 0.05 to 0.30;
forming a polysilicon layer on the gate insulating film material;
patterning the gate insulating film material and the polysilicon layer to form a gate insulating film and a gate electrode material, respectively;
introducing a conductive material into the gate electrode material to form a gate electrode; and
forming a source area and a drain area in the semiconductor layer on both sides sandwiching the gate electrode.

10. The method of manufacturing a semiconductor device according to claim 9, wherein in forming the gate insulating film material, the gate insulating film material is formed by an ALD (Atomic Layer Deposition) method.

11. The method of manufacturing a semiconductor device according to claim 9, wherein in forming the gate insulating film material, the gate insulating film material of film thickness 1 to 3 nm is formed.

12. The method of manufacturing the semiconductor device according to claim 9, wherein the forming the gate electrode comprises:
depositing a metal layer on the gate electrode material; and
reacting the gate electrode material with metal by carrying out thermal treatment to form the gate electrode comprising metal silicide.
